(19) United States
(12) Patent Application Publication
(10) Pub. No.: US 2024/0258424 A1
(43) Pub. Date: Aug. 1, 2024

(54) SILICON CARBIDE SEMICONDUCTOR DEVICE AND METHOD OF MANUFACTURING THE SAME

(71) Applicant: FUJI ELECTRIC CO., LTD., Kawasaki-shi (JP)

(72) Inventor: Yoshiyuki SAKAI, Matsumoto-city (JP)

(73) Assignee: FUJI ELECTRIC CO., LTD., Kawasaki-shi (JP)

(21) Appl. No.: 18/519,738

(22) Filed: Nov. 27, 2023

(30) Foreign Application Priority Data
Jan. 26, 2023 (JP) 2023-010169

(51) Int. Cl. H01L 29/78; H01L 21/04; H01L 29/06; H01L 29/08; H01L 29/10; H01L 29/16; H01L 29/66

(52) U.S. Cl. CPC H01L 29/7813; H01L 21/0465; H01L 29/063; H01L 29/086; H01L 29/1095; H01L 29/1608; H01L 29/66068

(57) ABSTRACT

A silicon carbide semiconductor device includes: a drift layer of a first conductivity-type including silicon carbide; a base region of a second conductivity-type provided on a top surface side of the drift layer; a main region of the first conductivity-type provided on a top surface side of the base region; a gate electrode buried inside a trench with a gate insulating film interposed; and a main electrode provided in contact with the main region, wherein the main region includes a first region with a bottom surface in contact with the base region, and a second region including a 3C structure and provided at an upper part of the first region separately from the gate insulating film inside the trench so as to be in contact with the main electrode.

### CROSS-REFERENCE TO RELATED APPLICATION

This application claims benefit of priority under 35 USC 119 based on Japanese Patent Application No. 2023-010169 filed on Jan. 26, 2023, the entire contents of which are incorporated by reference herein.

### BACKGROUND OF THE INVENTION

### 1. Field of the Invention

The present invention relates to a silicon carbide (SiC) semiconductor device including SiC and a method of manufacturing the same.

### 2. Description of the Related Art

JP 2009-49198 A discloses a semiconductor device obtained by implanting impurity ions of phosphorus into a silicon carbide substrate of hexagonal single crystals to form an amorphous layer, subjecting the amorphous layer to heat treatment to be recrystallized into n-type silicon carbide of cubic single crystals, and vapor-depositing nickel on the top surface of the n-type silicon carbide to form an electrode.

WO 2017/042963 A1 discloses a semiconductor device including an n′-type epitaxially-grown layer grown on a first main surface of an n⁺-type SiC substrate including 4H—SiC, an n⁺-type source region formed in the n⁻ type epitaxially-grown layer, and an n⁺-type 3C—SiC region and a p⁺-type potential fixation region each formed in the n⁺-type source region, in which a barrier metal film is formed in contact with the n⁺-type 3C—SiC region and the p⁺-type potential fixation region, and a source wiring electrode is further formed on the barrier metal film.

A study of improving trench-gate SiC semiconductor devices has been promoted that have a configuration in which a source region (a main region) includes 3C—SiC so as to be in ohmic contact with a source electrode (a main electrode).

However, since 3C—SiC has greater crystal defects than 4H—SiC and tends to lead the surface to be roughened, the case of including 3C—SiC has a problem of a leak current that would flow between the gate electrode and the source region.

### SUMMARY OF THE INVENTION

In view of the foregoing problems, the present invention provides a trench-gate SiC semiconductor device having a configuration capable of leading a main region to be in ohmic contact with a main electrode, and avoiding a leak current between a gate electrode and the main region.

An aspect of the present invention inheres in a SiC semiconductor device including: a drift layer of a first conductivity-type including silicon carbide; a base region of a second conductivity-type including silicon carbide provided on a top surface side of the drift layer; a main region of the first conductivity-type including silicon carbide provided on a top surface side of the base region; a gate insulating film provided inside a trench penetrating the main region and the base region; a gate electrode buried inside the trench with the gate insulating film interposed; and a main electrode provided in contact with the main region, wherein the main region includes a first region with a bottom surface in contact with the base region, and a second region including a 3C structure and provided at an upper part of the first region separately from the gate insulating film inside the trench so as to be in contact with the main electrode.

Another aspect of the present invention inheres in a method of manufacturing a SiC semiconductor device, including: forming a base region of a second conductivity-type including silicon carbide on a top surface side of a drift layer of a first conductivity-type including silicon carbide; forming a main region of the first conductivity-type including silicon carbide on a top surface side of the base region; digging a trench penetrating the main region and the base region; forming a gate insulating film inside the trench; burying a gate electrode inside the trench with the gate insulating film interposed; and forming a main electrode so as to be in contact with the main region, wherein the forming the main region includes forming a first region of the first conductivity-type at an upper part of the base region, and forming a second region including a 3C structure at an upper part of the first region separately from the gate insulating film inside the trench so as to be in contact with the main electrode.

### BRIEF DESCRIPTION OF THE DRAWINGS

FIG. 1 is a schematic cross-sectional view illustrating an example of a SiC semiconductor device according to a first embodiment;

FIG. 2 is an enlarged schematic cross-sectional view of region A in FIG. 1:

FIG. 3 is a schematic cross-sectional view illustrating a SiC semiconductor device of a comparative example;

FIG. 4 is a flowchart of a method of manufacturing the SiC semiconductor device according to the first embodiment:

FIG. 5 is a schematic cross-sectional view for explaining an example of the method of manufacturing the SiC semiconductor device according to the first embodiment;

FIG. 6 is a schematic cross-sectional view continued from FIG. 5, for explaining the example of the method of manufacturing the SiC semiconductor device according to the first embodiment:

FIG. 7 is a schematic cross-sectional view continued from FIG. 6, for explaining the example of the method of manufacturing the SiC semiconductor device according to the first embodiment;

FIG. 8 is a schematic cross-sectional view continued from FIG. 7, for explaining the example of the method of manufacturing the SiC semiconductor device according to the first embodiment;

FIG. 9 is a schematic cross-sectional view continued from FIG. 8, for explaining the example of the method of manufacturing the SiC semiconductor device according to the first embodiment:

FIG. 10 is a schematic cross-sectional view continued from FIG. 9, for explaining the example of the method of manufacturing the SiC semiconductor device according to the first embodiment;

FIG. 11 is a schematic cross-sectional view continued from FIG. 10, for explaining the example of the method of manufacturing the SiC semiconductor device according to the first embodiment;

FIG. 12 is a schematic cross-sectional view continued from FIG. 11, for explaining the example of the method of manufacturing the SiC semiconductor device according to the first embodiment;

FIG. 13 is a schematic cross-sectional view continued from FIG. 12, for explaining the example of the method of manufacturing the SiC semiconductor device according to the first embodiment:

FIG. 14 is a schematic cross-sectional view continued from FIG. 13, for explaining the example of the method of manufacturing the SiC semiconductor device according to the first embodiment;

FIG. 15 is a schematic cross-sectional view continued from FIG. 14, for explaining the example of the method of manufacturing the SiC semiconductor device according to the first embodiment;

FIG. 16 is a schematic cross-sectional view illustrating an example of a SiC semiconductor device according to a second embodiment;

FIG. 17 is a flowchart of a method of manufacturing the SiC semiconductor device according to the second embodiment;

FIG. 18 is a schematic cross-sectional view for explaining an example of the method of manufacturing the SiC semiconductor device according to the second embodiment; and

FIG. 19 is a schematic cross-sectional view illustrating an example of a SiC semiconductor device according to a third embodiment.

### DETAILED DESCRIPTION

With reference to the drawings, first to third embodiments of the present invention will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to third embodiments described below merely illustrate schematically devices and methods for specifying and giving shapes to the technical idea of the present invention, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOS transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, an “upper surface” may be read as “front surface”, and a “lower surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “-”. However, even when the semiconductor regions are denoted by the same reference symbols “n” and “n”, it is not indicated that the semiconductor regions have exactly the same impurity concentration or the same specific resistance.

In addition, a crystal polymorphism is present in SiC crystals, and main examples include 3C of a cubic crystal, and 4H and 6H of a hexagonal crystal. A bandgap at room temperature is reported that is 2.23 eV in 3C—SiC. 3.26 eV in 4H—SiC, and 3.02 eV in 6H—SiC. The following embodiments are illustrated with a case of mainly using 4H—SiC and 3C—SiC.

### First Embodiment

### <Structure of SiC Semiconductor Device>

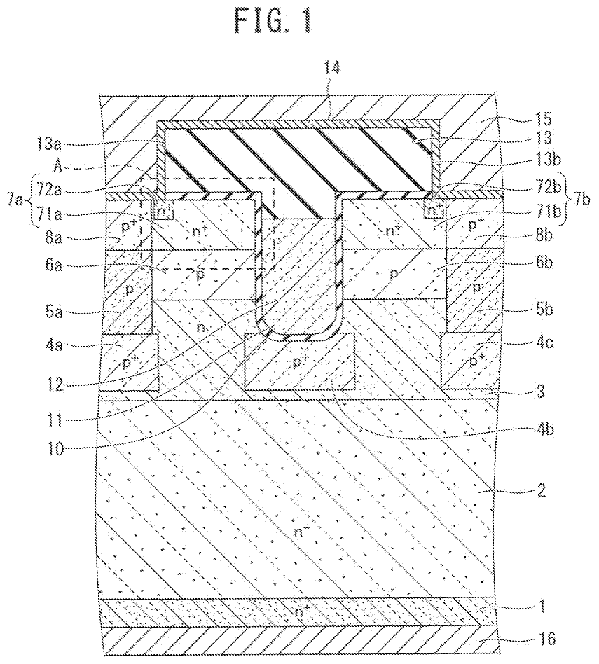

A SiC semiconductor device according to a first embodiment is illustrated below with a case of including a trench-gate MOSFET as an active element, as illustrated in FIG. 1. While FIG. 1 illustrates a unit cell including an insulated gate electrode structure (11, 12) buried in a single trench 10, the plural unit cells are repeatedly arranged in an actual case.

The SiC semiconductor device according to the first embodiment includes a drift layer 2 of a first conductivity-type (n⁻-type). The drift layer 2 is an epitaxially-grown layer including SiC such as 4H-SiC, for example. The drift layer 2 has an impurity concentration in a range of about 1×10¹⁵ cm⁻³ or greater and 5×10¹⁶ cm⁻³ or less, for example. The drift layer 2 has a thickness in a range of about 1 micrometer or greater and 100 micrometers or smaller, for example. The impurity concentration and the thickness of the drift layer 2 can be adjusted as appropriate depending on the breakdown voltage specifications, for example.

A current spreading layer (CSL) 3 of a first conductivity-type (n-type) having a higher impurity concentration than the drift layer 2 is selectively deposited on the top surface side of the drift layer 2. The bottom surface of the current spreading layer 3 is in contact with the top surface of the drift layer 2. The current spreading layer 3 is an epitaxially-grown layer including SiC such as 4H—SiC, for example. The current spreading layer 3 has an impurity concentration in a range of about 5×10¹⁶ cm⁻³ or greater and 5×10¹² cm⁻³ or less, for example. The present embodiment does not necessarily include the current spreading layer 3, and the drift layer 2 may be arranged to extend toward a region corresponding to the current spreading layer 3 when not provided.

Base regions 6a and 6b of a second conductivity-type (p-type) are deposited on the top surface side of the current spreading layer 3. The respective bottom surfaces of the base regions 6a and 6b are in contact with the top surface of the current spreading layer 3. The respective bottom surfaces of the base regions 6a and 6b are in contact with the top surface of the drift layer 2 when the current spreading layer 3 is not provided. The base regions 6a and 6b are each an epitaxially-grown layer including SiC such as 4H-SiC, for example. The base regions 6a and 6b may each be a region obtained such that p-type impurity ions are implanted into the current spreading layer 3. The respective base regions 6a and 6b have an impurity concentration in a range of about 1×10¹⁶ cm⁻³ or greater and 1×10¹⁸ cm⁻³ or less.

First main regions (source regions) 7a and 7b of the first conductivity-type (n⁺-type) having a higher impurity concentration than the drift layer 2 are selectively deposited on the top surface side of the base regions 6a and 6b. The source regions 7a and 7b are each a region including SiC obtained such that n-type impurity ions are implanted into the base regions 6a and 6b, for example.

The source region 7a includes a source expansion part (a first region) 71a of n⁺-type with the bottom surface in contact with the top surface of the base region 6a, and a source contact part (a second region) 72a of n⁺-type provided at a part of the upper part (on the top surface side) of the source expansion part 71a. The source region 7b includes a source expansion part (a first region) 71b of n⁺-type with the bottom surface in contact with the top surface of the base region 6b, and a source contact part (a second region) 72b of n⁺-type provided at a part of the upper part (on the top surface side) of the source expansion part 71b. The respective source regions 7a and 7b are described in detail below.

The trench 10 is provided to penetrate the respective source regions 7a and 7b and the respective base regions 6a and 6b from the top surfaces of the source regions 7a and 7b in the normal direction with respect to the top surface of the respective source regions 7a and 7b (in the depth direction). The bottom surface of the trench 10 reaches the current spreading layer 3. The trench 10 has a width of about one micrometer or smaller, for example. The source region 7a and the base region 6a are in contact with the side surface of the trench 10 on the left side. The source region 7b and the base region 6b are in contact with the side surface of the trench 10 on the right side. The trench 10 may have a planar pattern extending in a stripe state in the backside direction and the front direction in the sheet of FIG. 1, or may have a dot-like planar pattern.

A gate insulating film 11 is provided along the bottom surface and the side surfaces on both sides of the trench 10. A gate electrode 12 is buried inside the trench 10 with the gate insulating film 11 interposed. The gate insulating film 11 and the gate electrode 12 implement the trench-gate type insulated gate electrode structure (11, 12).

The gate insulating film 11 as used herein can be a single film of a silicon oxide film (a SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 12 can be made of a polysilicon layer (a doped polysilicon layer) heavily doped with p-type or n-type impurity ions or made of a layer including refractory metal such as titanium (Ti), tungsten (W), or nickel (Ni), for example.

A gate bottom protection region 4b of the second conductivity-type (p⁺-type) is provided at the bottom of the trench 10 inside the current spreading layer 3. The top surface of the gate bottom protection region 4b is in contact with the bottom surface of the trench 10. The top surface of the gate bottom protection region 4b is not necessarily in contact with the bottom surface of the trench 10. The gate bottom protection region 4b is a region including SiC obtained such that p-type impurity ions are implanted into the current spreading layer 3, for example. The gate bottom protection region 4b has an impurity concentration in a range of about 1×10¹⁷ cm⁻³ or greater and 1×10¹⁹ cm⁻³ or less, for example.

First buried regions 4a and 4c of the second conductivity-type (p⁺-type) are provided inside the current spreading layer 3 separately from the gate bottom protection region 4b. The first buried regions 4a and 4c are located at substantially the same depth as the gate bottom protection region 4b. The first buried regions 4a and 4c are each a region including SiC obtained such that p-type impurity ions are implanted into the current spreading layer 3, for example. The respective first buried regions 4a and 4c have an impurity concentration in a range of about 1×10¹⁷ cm⁻³ or greater and 1×10¹⁹ cm⁻³ or less, for example. A connection part of p⁺-type for connecting the respective first buried regions 4a and 4c and the gate bottom protection region 4b together may be selectively provided on the front side or the back side in the sheet of FIG. 1.

Second buried regions 5a and 5b of the second conductivity-type (p-type) are provided on the top surface side of the first buried regions 4a and 4c at the upper part of the current spreading layer 3. The second buried regions 5a and 5b electrically connect the first buried regions 4a and 4c and the base regions 6a and 6b to each other. The bottom surfaces of the second buried regions 5a and 5b are in contact with the top surfaces of the first buried regions 4a and 4c. The side surfaces of the second buried regions 5a and 5b are in contact with the current spreading layer 3 and the base regions 6a and 6b. The second buried regions 5a and 5b are each a region including SiC obtained by implantation of p-type impurity ions into the current spreading layer 3 and the base regions 6a and 6b, for example. The second buried regions 5a and 5b may have substantially the same impurity concentration as the first buried regions 4a and 4c, or may have either a lower impurity concentration or a higher impurity concentration than the first buried regions 4a and 4c. The impurity concentration of the respective second buried regions 5a and 5b is in a range of about 1×10¹⁷ cm⁻³ or greater and 1×10¹⁹ cm⁻³ or less, for example.

Base contact regions 8a and 8b of p⁺-type having a higher impurity concentration than the second buried regions 5a and 5b are deposited on the top surface side of the second buried regions 5a and 5b. The base contact regions 8a and 8b are each a region including SiC obtained by implantation of p-type impurity ions into the base regions 6a and 6b, for example. The base contact regions 8a and 8b have an impurity concentration in a range of about 5×10¹⁸ cm⁻³ or greater and 5×10²⁰ cm⁻³ or less, for example. The base contact regions 8a and 8b may include either 3C—SiC or 4H—SiC.

The bottom surface of the base contact region 5a is in contact with the top surface of the second buried region 5a, and the side surface of the base contact region 8a is in contact with the source expansion part 71a of the source region 7a. The bottom surface of the base contact region 8b is in contact with the top surface of the second buried region 5b, and the side surface of the base contact region 8b is in contact with the source expansion part 71b of the source region 7b. The respective bottom surfaces of the base contact regions 8a and 8b are located at substantially the same depth as the respective bottom surfaces of the source expansion parts 71a and 71b of the source regions 7a and 7b, but may be either shallower than or deeper than the respective bottom surfaces of the source expansion parts 71a and 71b of the source regions 7a and 7b instead. The respective top surfaces of the second buried regions 5a and 5b are not necessarily in contact with the respective bottom surfaces of the p⁺-type base contact regions 8a and 8b.

An interlayer insulating film 13 is deposited on the top surface side of the gate electrode 12. The interlayer insulating film 13 is a single-layer film, such as a borophosphosilicate glass film (BPSG), a phosphosilicate glass film (a PSG film), a non-doped silicon oxide film without containing phosphorus (P) or boron (B) which is referred to as a non-doped silicate glass (NSG) film, a borosilicate glass film (a BSG film), or a silicon nitride (Si₁₃N₄) film, or a stacked-layer film including the above films stacked on one another. The interlayer insulating film 13 is provided with contact holes 13a and 13b so as to expose at least a part of the respective top surfaces of the source contact parts 72a and 72b and the base contact regions 8a and 8b.

A first main electrode (a source electrode) (14, 15) is provided to cover the interlayer insulating film 13 and the respective top surfaces of the source contact parts 72a and 72b and the base contact regions 8a and 8b exposed to the contact holes 13a and 13b of the interlayer insulating film 13. The source electrode (14, 15) includes a barrier metal layer 14 as a lower layer and a source wiring electrode 15 as an upper layer. The barrier metal layer 14 includes metal such as titanium nitride (TiN), titanium (Ti), or a stacked-layer structure of TiN/Ti including Ti as a lower layer, for example. The barrier metal layer 14 is directly in contact with the source contact parts 72a and 72b and the base contact regions 8a and 8b, and also in ohmic contact with the source contact parts 72a and 72b and the base contact regions 8a and 8b at a low resistance.

The source wiring electrode 15 is electrically connected to the respective source regions 7a and 7b and the respective base contact regions 8a and 8b via the barrier metal layer 14. The source wiring electrode 15 is provided separately from a gate wiring electrode (not illustrated) electrically connected to the gate electrode 12. The source wiring electrode 15 includes metal such as aluminum (Al), aluminum-silicon (Al—Si), aluminum-copper (Al—Cu), or copper (Cu), for example.

A second main region (a drain region) 1 of the first conductivity-type (n⁺-type) having a higher impurity concentration than the drift layer 2 is deposited on the bottom surface side of the drift layer 2. The drain region 1 is made of a semiconductor substrate (a SiC substrate) including 4H—SIC, for example. The drain region 1 has an impurity concentration in a range of about 1×10¹⁹ cm⁻³ or greater and 3×10²⁰ cm⁻³ or less, for example. The drain region 1 has a thickness in a range of about 30 micrometers or greater and 500 micrometers or smaller, for example. A dislocation conversion layer or a recombination promotion layer having a higher impurity concentration than the drift layer 2 and having a lower impurity concentration than the drain region 1 may be provided as an n-type buffer layer between the drift layer 2 and the drain region 1.

A second main electrode (a drain electrode) 16 is deposited on the bottom surface side of the drain region 1. The drain electrode 16 can be a single-layer film including gold (Au), or a metal film including titanium (Ti), nickel (Ni), and Au stacked in this order from the drain region 1 side, and may be further provided with a metal film including molybdenum (Mo) or tungsten (W), for example, as the lowermost layer. A drain contact layer such as nickel silicide (NiSiₓ) film for ensuring an ohmic contact may be provided between the drain region 1 and the drain electrode 16.

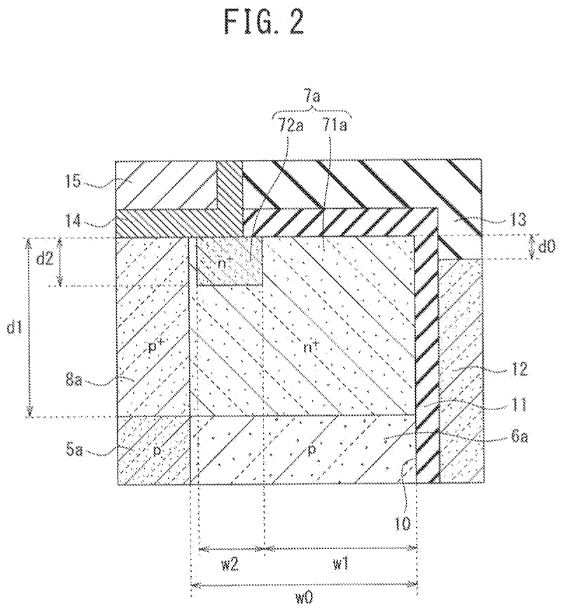

FIG. 2 is an enlarged cross-sectional view of region A including the source expansion part 71a and the source contact part 72a of the source region 7a, the first buried regions 5a and 5b, the base contact regions 8a and 8b, the gate insulating film 11, and the gate electrode 12 indicated by the broken line in FIG. 1. The configurations of the source expansion part 71a and the source contact part 72a of the source region 7a, and the positional relation between the source expansion part 71a and the source contact part 72a of the source region 7a and the second buried regions 5a and 5b, the base contact regions 8a and 8b, the gate insulating film 11, and the gate electrode 12 are described below with reference to FIG. 2.

A depth (a thickness of the source expansion part 71a) d1 from the top surface to the bottom surface of the source expansion part 71a is in a range of about 150 nanometers or greater and 450 nanometers or smaller, for example. A width W0 of the source expansion part 71a is in a range of about 400 nanometers or greater and 1000 nanometers or smaller, for example. The side surface of the source expansion part 71a is directly in contact with the gate insulating film 11, and is opposed to the gate electrode 12 with the gate insulating film 11 interposed.

The source expansion part 71a is a region having fewer crystal defects than the source contact part 72a while hardly taking over the crystal defects in the source contact part 72a. The source expansion part 71a mainly includes 4H—SiC (a 4C structure). The proportion of 4H—SiC included in the source expansion part 71a is in a range of about 90% or greater and 100% or smaller, for example. The source expansion part 71a may further have an amorphous structure and include a small amount of 3C—SiC other than 4H—SiC, for example. The source expansion part 71a has a lower impurity concentration than the source contact part 72a or has substantially the same impurity concentration as the source contact part 72a. The impurity concentration of the source expansion part 71a is in a range of about 1×10¹⁶ cm⁻³ or greater and 1×10¹⁹ cm⁻³ or less, for example. The source expansion part 71a includes nitrogen (N) as n-type impurity ions, for example. The source expansion part 71a may include phosphorus (P) or arsenic (As) as n-type impurity ions.

A width W1 by which the source contact part 72a is separated from the gate insulating film 11 deposited inside the trench 10, which is a width of the source expansion part 71a interposed between the source contact part 72a and the gate insulating film 11, is set in a range of about 100 nanometers or greater and 500 nanometers or smaller, for example. Setting the width W1 to 100 nanometers or greater can effectively avoid a gate leak current described below. A width W2 of the source contact part 72a is set in a range of 300 nanometers or greater and 500 nanometers or smaller, for example. A depth d2 from the top surface to the bottom surface of the source contact part 72a (a thickness of the source contact part 72a) is set in a range of about 30 nanometers or greater and 100 nanometers or smaller, for example.

The source contact part 72a is separated from the gate insulating film 11 inside the trench 10. While FIG. 2 illustrates the case in which the end part (the side surface) of the source contact part 72a on the right side is shifted toward the gate electrode 12 from the end part of the contact hole 13a of the interlayer insulating film 13, which is the end part of each of the gate insulating film 11 and the interlayer insulating film 13, the end part of the source contact part 72a may conform to the end part of the contact hole 13a. Further, the end part (the side surface) of the source contact part 72a on the left side is separated from the base contact region 8a, but may be in contact with the base contact region 8a instead.

The source contact part 72a is a region including 3C—SiC (a 3C structure). The proportion of 3C-SiC included in the source contact part 72a is in a range of about 10% or greater and 100% or smaller, for example. The source contact part 72a may have a mixed-crystal structure of 3C—SiC and 4H—SiC. The source contact part 72a may further have an amorphous structure and include 4H—SiC other than 3C—SiC, for example. The source contact part 72a when including 3C—SiC, which has a narrower bandgap than 4H—SiC, can be led to be in ohmic contact with the source electrode (14, 15) at a low resistance. To achieve a good ohmic contact with the source electrode (14, 15), the proportion of 3C-SiC included in the source contact part 72a is preferably 10% or greater.

The source contact part 72a has a higher impurity concentration than the source expansion part 71a. The impurity concentration of the source contact part 72a is in a range of about 1×10¹⁹ cm⁻³ or greater and 1×10²² cm⁻³ or less, for example. The source contact part 72a includes phosphorus (P) or arsenic (As) as n-type impurity ions, for example. The source contact part 72a may include nitrogen (N) as n-type impurity ions. The source contact part 72a may include P. As, and N combined as appropriate as n-type impurity ions. The source contact part 72a may further include an inactive element such as argon (Ar) or helium (He).

The crystal structures of the source expansion part 71a and the source contact part 72a can be formed independently of each other such that some conditions such as the element to be implanted, the temperature during the ion implantation, the dose (the impurity concentration), and the activation temperature are changed for each of the source expansion part 71a and the source contact part 72a. The process of forming the source contact part 72a including 3C—SiC implants n-type impurity ions or ab inactive element having a high impurity concentration (a high dose) to 4H—SiC at a room temperature so as to destroy 4H—SiC to form an amorphous structure by use of damage during the ion implantation. The execution of the following activation annealing leads the amorphous structure to turn to 3C—SiC when recrystallized, so as to form the source contact part 72a including 3C—SiC.

The process of forming the source expansion part 71a including 4H—SiC implants n-type impurity ions to 4H—SiC at a high temperature (for example, about at 500° C.) at an impurity concentration (with a dose) that can sufficiently avoid destruction of the structure of 4H—SiC, so as to keep 4H—SiC to form the source expansion part 71a.

The respective crystal structures of the source expansion part 71a and the source contact part 72a can be measured (observed) such that a ratio of the areas of the crystal structures on the surfaces is measured by use of a field-emission scanning electron microscope (FE-SEM) by electron backscatter diffraction (EBSD), for example. The present embodiment executed the measurement, as an example, such that samples were prepared under the common conditions of the element of the impurity ions to be implanted, the dose (the impurity concentration), and the activation temperature, while two different temperatures were used upon the ion implantation that were 500° C. and a room temperature (25° C.) so as to be measured by use of FE-SEM and EBSD. The proportion of 4H—SIC on the surface in the sample obtained at 500° C. was 100%. The proportion of 4H—SiC on the surface in the sample obtained at the room temperature was 86%, while the proportion of 3C—SiC was 14%.

The top surface (the upper end) of the gate electrode 12 at the end part in contact with the gate insulating film 11 is located at a position shallower than the bottom surface of the source contact part 72a. A drop amount do of the gate electrode 12 from the top surface of the source expansion part 71a is in a range of about 10 nanometers or greater and 300 nanometers or smaller, for example. The drop amount do of the gate electrode 12 and the position of the top surface of the gate electrode 12 in contact with the gate insulating film 11 can be regulated such that the etching conditions for the gate electrode 12 are adjusted, for example. Decreasing the drop amount do of the gate electrode 12 and arranging the top surface of the gate electrode 12 to be shallower than the bottom surface of the source contact part 72a can reduce a variation in gate threshold voltage. The top surface at the position corresponding to the end part of the gate electrode 12 in contact with the gate insulating film 11 is located at a position shallower than the bottom surface of the source contact part 72a. The top surface of the gate electrode 12 at the position of the end part in contact with the gate insulating film 11 may be located at a position deeper than the bottom surface of the source contact part 72a instead. The top surface of the gate insulating film 11 only needs to be located at a position higher than the top surface of the gate electrode 12, and may be located on the top surface of the source expansion part 71a.

The source expansion part 71b and the source contact part 72b of the source region 7b illustrated in FIG. 1 have the configurations common to those of the source expansion part 71a and the source contact part 72a of the source region 7a, respectively, and overlapping explanations are not repeated below. The positional relation regarding the source expansion part 71b and the source contact part 72b of the source region 7b with respect to the second buried region 5b, the base contact region 8b, the gate insulating film 11, and the gate electrode 12 is common to that regarding the source expansion part 71a and the source contact part 72a of the source region 7a with respect to the second buried region 5a, the base contact region 8a, the gate insulating film 11, and the gate electrode 12 illustrated in FIG. 2, and overlapping explanations are not repeated below.

The SiC semiconductor device according to the first embodiment during the operation applies a positive voltage to the drain electrode 16 while using the source electrode (14, 15) as a ground potential, and causes an inversion layer (a channel) to be formed in the respective base regions 6a and 6b toward the side surfaces of the trench 10 so as to be in the ON-state when a positive voltage of a threshold or greater is applied to the gate electrode 12. In the ON-state, a current flows from the drain electrode 16 toward the source electrode (14, 15) through the drain region 1, the drift layer 2, the current spreading layer 3, the inversion layers of the base regions 6a and 6b, and the source regions 7a and 7b. When the voltage applied to the gate electrode 12 is smaller than the threshold, the SiC semiconductor device is led to be the OFF-state since no inversion layer is formed in the base region 6a or 6b, and no current flows from the drain electrode 16 toward the source electrode (14, 15).

The SiC semiconductor device according to the first embodiment, in which the source contact parts 72a and 72b of the source regions 7a and 7b including 3C—SiC are in contact with the source electrode (14, 15), leads the contact bonding surfaces of the source regions 7a and 7b to turn to 3C—SiC. This configuration can lead the source contact parts 72a and 72b to be in ohmic contact with the source electrode (14, 15) at a low resistance without a provision of a silicide layer including nickel (Ni) silicide or the like. The present embodiment thus can avoid a problem of separation of such a silicide layer, as compared with a case of including the silicide layer.

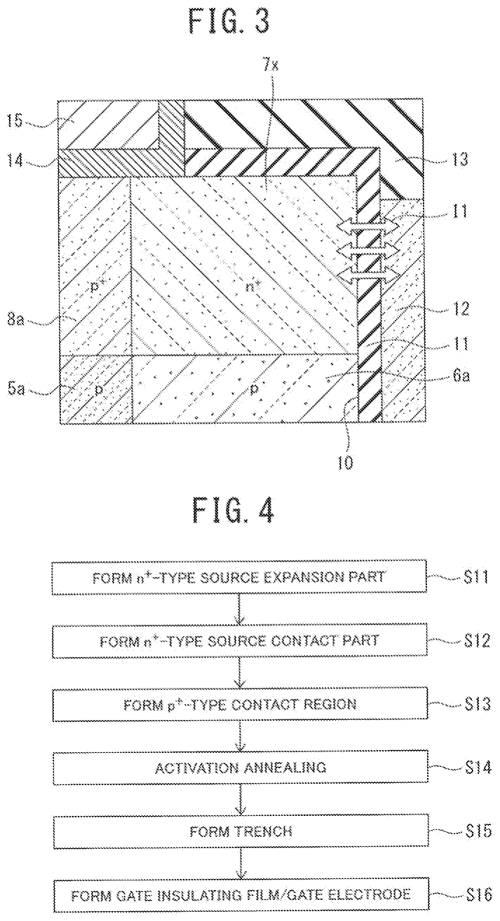

When it is assumed, as illustrated in FIG. 3, that a source region 7x is only composed of a region including 3C—SiC, and is directly in contact with the gate insulating film 11, the source region 7x including 3C—SiC could be in ohmic contact with the source electrode (14, 15). However, since 3C—SiC tends to have crystal defects and cause a roughened surface more than 4H—SiC, a leak current Il could flow between the gate electrode 12 and the source region 7x.

As compared with the conventional case described above, the SiC semiconductor device according to the first embodiment has the configuration in which the source contact part 72a of the source region 7a including 3C—SiC having a relatively large amount of crystal defects is separated from the gate insulating film 11 and the gate electrode 12 provided inside the trench 10 so as not to be directly in contact with the gate insulating film 11 inside the trench 10. Further, the source expansion part 71a of the source region 7a including 4C—SiC having a relatively small amount of crystal defects is directly in contact with the gate insulating film 11 inside the trench 10 so as to be opposed to the gate electrode 12 with the gate insulating film 11 interposed. The present embodiment thus can suppress a cause of a leak current flowing between the source region 7a and the gate electrode 12.

### <Method of Manufacturing Semiconductor Device>

An example of a method of manufacturing the SiC semiconductor device according to the first embodiment is described below. It should be understood that the method of manufacturing the SiC semiconductor device described below is an example, and the SiC semiconductor device can be manufactured by other methods including modified examples of this embodiment within the scope of the appended claims. FIG. 4 is a flowchart showing a procedure of a part of the method of manufacturing the SiC semiconductor device according to the first embodiment. The following explanations are made with reference to FIG. 4 as necessary.

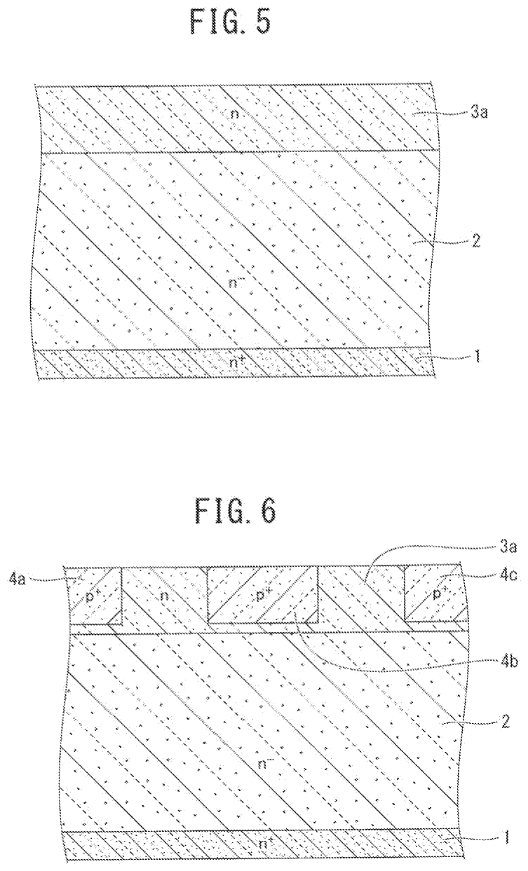

First, the semiconductor substrate (the SiC substrate) 1 (refer to FIG. 1) including 4H—SiC of n⁺-type doped with n-type impurity ions such as nitrogen (N) is prepared. The top surface of the SiC substrate 1 has an off-angle of three to eight degrees with respect to a (0001) plane, for example. The drift layer 2 (refer to FIG. 1) including 4H—SiC of n-type doped with n-type impurity ions such as N and having a lower impurity concentration than the SiC substrate 1 is then epitaxially grown on the top surface of the SiC substrate 1. Next, as illustrated in FIG. 5, an n-type layer 3a including 4H—SiC of n-type doped with n-type impurity ions such as N and having a higher impurity concentration than the drift layer 2 is epitaxially grown on the top surface of the drift layer 2. The n-type layer 3a may be formed by the implantation of n-type impurity ions such as nitrogen (N) into the upper part of the drift layer 2, instead.

Next, an oxide film is deposited on the top surface of the n-type layer 3a by chemical vapor deposition (CVD), for example. A photoresist film is then applied to the top surface of the oxide film, and the oxide film is delineated by photolithography and dry etching, for example. Using the delineated oxide film as a mask for ion implantation, p-type impurity ions such as aluminum (Al) are selectively implanted. Instead of the oxide film, a photoresist film may be used as a mask for ion implantation. The oxide film used as the mask for ion implantation is then removed. This step selectively provides the p⁺-type first buried regions 4a and 4c and the p⁺-type gate bottom protection region 4b at the upper part of the n-type layer 3a, as illustrated in FIG. 6.

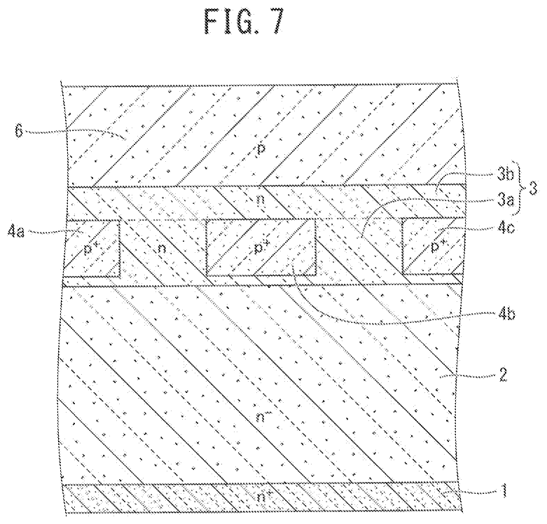

Next, an n-type layer 3b (refer to FIG. 7) including 4H—SiC of n-type is epitaxially grown on the respective top surfaces of the n-type layer 3a, the first buried regions 4a and 4c, and the gate bottom protection region 4b. This step provides the current spreading layer 3 including the n-type layer 3a and the n-type layer 3b. Next, as illustrated in FIG. 7, the base region 6 including 4H—SiC of p-type is epitaxially grown on the top surface of the current spreading layer 3.

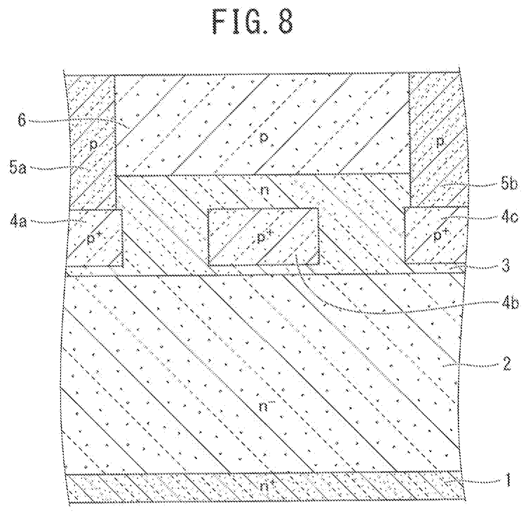

Next, an oxide film is deposited on the top surface of the base region 6 by CVD or the like. A photoresist film is then applied to the top surface of the oxide film, and the oxide film is delineated by photolithography and dry etching. Using the delineated oxide film as a mask for ion implantation, p-type impurity ions such as aluminum (Al) are selectively implanted. Instead of the oxide film, a photoresist film may be used as a mask for ion implantation. The oxide film used as the mask for ion implantation is then removed. This step selectively provides the p-type second buried regions 5a and 5b on the top surface side of the first buried regions 4a and 4c, as illustrated in FIG. 8.

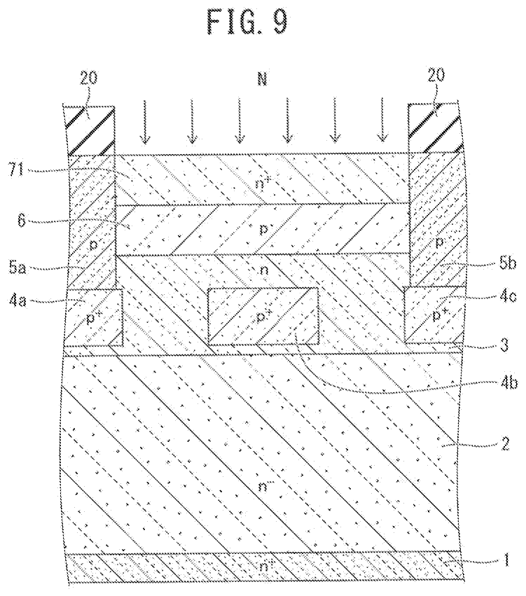

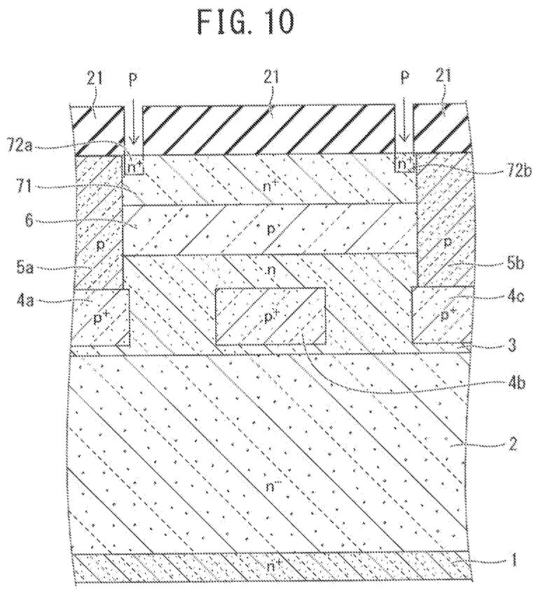

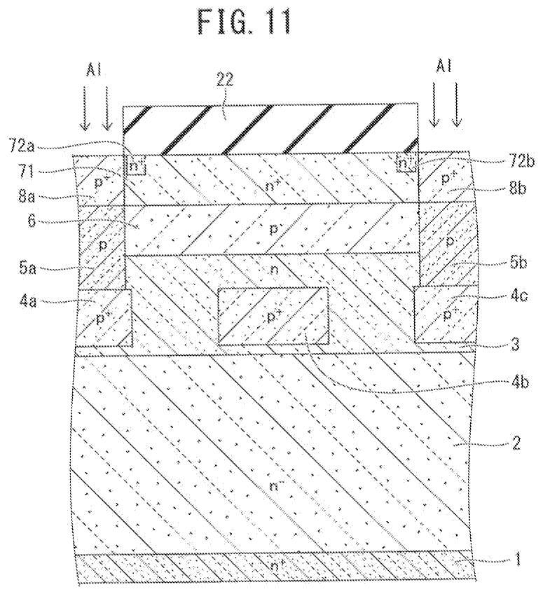

Next, a step of forming an n⁺-type source expansion part in step S11 shown in FIG. 4 is executed. The step of forming the n′-type source expansion part deposits an oxide film 20 (refer to FIG. 9) on the top surface of the base region 6 by CVD or the like. A photoresist film is then applied to the top surface of the oxide film 20, and the oxide film 20 is delineated by photolithography and dry etching. Using the delineated oxide film 20 as a mask for ion implantation, n-type impurity ions such as nitrogen (N) are implanted, as illustrated in FIG. 9. Instead of the oxide film 20, a photoresist film may be used as a mask for ion implantation. This step provides the n⁺-type source expansion part 71 at the upper part of the base region 6.

Upon the ion implantation for the source expansion part 71, the use of phosphorus (P: element number 15) having a relatively small atomic number as the n-type impurity ions is preferable, and the use of N (element number 7) having a smaller atomic number is more preferable in order to have less damage than the ion implantation for the source contact parts 72a and 72b described below. Instead of P or N, arsenic (As; element number 33) having a relatively large atomic number may be implanted. The temperature during the ion implantation in this step is set to be higher than the temperature during the ion implantation for the source contact parts 72a and 72b described below, and is set in a range of 300° C. or higher and 600° ° C. or lower, for example. The dose of the impurity ions to be implanted is set such that the impurity concentration of the source expansion part 71 is set in a range of about 1×10¹⁶ cm⁻³ or greater and 1×10¹⁹ cm⁻³ or less, for example. The dose of the impurity ions to be implanted is set to about less than 2×10¹⁵ cm⁻², for example. The oxide film 20 used as the mask for ion implantation is then removed after the implantation of the impurity ions into the source expansion part 71.

Next, a step of forming an n⁺-type source contact part in step S12 shown in FIG. 4 is executed. The step of forming the n⁺-type source contact part deposits an oxide film 21 (refer to FIG. 10) on the top surface of the source expansion part 71 by CVD method or the like. A photoresist film is then applied to the top surface of the oxide film 21, and the oxide film 21 is delineated by photolithography and dry etching. Using the delineated oxide film 21 as a mask for ion implantation, n-type impurity ions such as phosphorus (P) are selectively implanted, as illustrated in FIG. 10. Instead of the oxide film 21, a photoresist film may be used as a mask for ion implantation. This step provides the n⁺-type source contact parts 72a and 72b on the top surface side of the source expansion part 71.

The execution of the ion implantation for the source contact parts 72a and 72b breaks the structure of 4H—SiC on the top surface side of the source expansion part 71 so as to form the amorphous structure. To have greater damage than the ion implantation for the source expansion part 71 described above, the use of P (element number 15) having a relatively large atomic number as the n-type impurity ions is preferable, and the use of arsenic (As: element number 33) having a greater atomic number is more preferable. Nitrogen (N) having a relatively small atomic number may be used instead. The same impurity ions may be implanted for forming the source contact parts 72a and 72b as the impurity ions implanted for forming the source expansion part 71 described above, or different impurity ions may be implanted instead. The temperature during the ion implantation in this step is set to be lower than the temperature during the ion implantation for the source expansion part 71 described above, and is set in a range of 20° C. or higher and 150° C. or lower, for example. The dose of the impurity ions to be implanted is set such that the impurity concentration of the source contact parts 72a and 72b is set in a range of about 1×10¹⁹ cm⁻³ or greater and 1×10²² cm⁻³ or less, for example, in total including the impurity ions implanted for forming the source expansion part 71 described above. The total dose of the impurity ions to be implanted including the dose of the impurity ions implanted to the source expansion part 71 described above is set to about 2×10¹⁵ cm 2 or greater, for example.

Upon the ion implantation for the source contact parts 72a and 72b, an inactive element such as argon (Ar) or helium (He) may be implanted instead of the n-type impurity ions. The dose of the inactive element to be implanted is adjusted such that the total dose including the dose of the impurity ions implanted for forming the source expansion part 71 described above is set to about 2×10¹⁵ cm 2 or greater, for example. When the inactive element is used for the ion implantation, the p-type impurity ions are implanted only to the source expansion part 71, and the source expansion part 71 and the source contact parts 72a and 72b thus have substantially the same impurity concentration. When the inactive element is used for the ion implantation, impurity ions may be implanted further to regions for forming the base contact regions 5a and 8b without being covered with the oxide film 21 so as to form the base contact regions 8a and 8b including 3C—SiC. The oxide film 21 used as the mask for ion implantation is then removed after the ion implantation for the source contact parts 72a and 72b.

Next, a step of forming a p⁺-type contact region in step S13 shown in FIG. 4 is executed. The step of forming the p⁺-type contact region deposits an oxide film 22 on the top surface of the base region 6 by CVD or the like. A photoresist film is then applied to the top surface of the oxide film 22, and the oxide film 22 is delineated by photolithography and dry etching. Using the delineated oxide film 22 as a mask for ion implantation, p-type impurity ions such as aluminum (Al) or boron (B) are implanted, as illustrated in FIG. 11. Instead of the oxide film 22, a photoresist film may be used as a mask for ion implantation. This step selectively provides the p⁺-type base contact regions 8a and 8b on the top surface side of the second buried regions 5a and 5b. The oxide film 22 used as the mask for ion implantation is then removed. The ion implantation for forming the base contact regions 8a and 8b may be executed by use of the common mask for ion implantation during the ion implantation for forming the second buried regions 5a and 5b.

The order of executing the step of forming the n⁺-type source expansion part in step S11, the step of forming the n⁺-type source contact part in step S12, and the step of forming the p⁺-type contact region in step S13 shown in FIG. 4 is not limited to this case, and may be changed as appropriate. For example, the step of forming the n⁺-type source expansion part in step S11 may be executed after the execution of the step of forming the n⁺-type source contact part in step S12.

Next, a step of activation annealing (heat treatment) in step S14 shown in FIG. 4 is executed. The activation annealing step is executed at a temperature of about 1600° C. or higher and 1900° C.′ or lower, for example, so as to collectively activate the p-type impurity ions or the n-type impurity ions implanted into the first buried regions 4a and 4b, the gate bottom protection region 4b, the second buried regions 5a and 5b, the source expansion part 71, the source contact parts 72a and 72b, the base contact regions 8a and 8b, and the like. At this point, the amorphous structure in the source contact parts 72a and 72b is recrystallized to turn to 3C—SiC, so as to form the source contact parts 72a and 72b including 3C—SiC.

While the single activation annealing is collectively executed after all of the ion implantation steps, the activation annealing may be executed several times independently after each of the ion implantation steps. Alternatively, the present embodiment may include a step of forming a cap film including carbon (C), executing the activation annealing after the execution of the covering with the cap film, and then removing the cap film after the activation annealing.

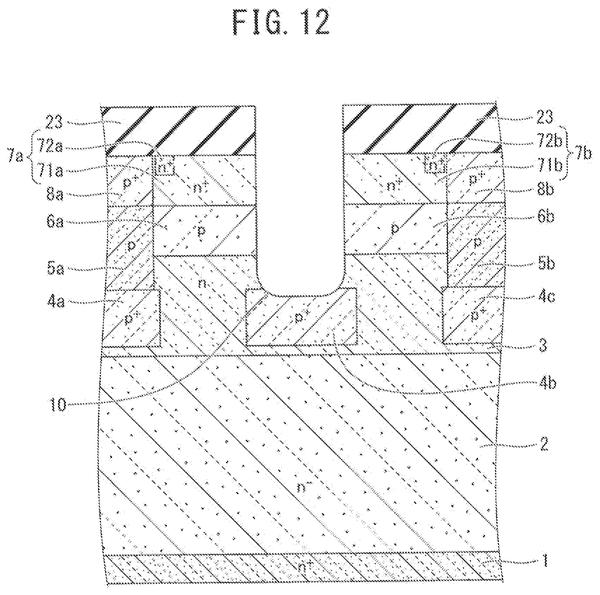

Next, a step of forming a trench in step S15 shown in FIG. 4 is executed. The step of forming the trench deposits an oxide film 23 (refer to FIG. 12) on the respective top surfaces of the base contact regions 8a and 8b and the source contact parts 72a and 72b by CVD or the like. A photoresist film is then applied to the top surface of the oxide film 23, and the oxide film 23 is delineated by photolithography and dry etching. Using the delineated oxide film 23 as a mask for etching, the trench 10 is selectively formed in the depth direction from the top surface of the source expansion part 71 by dry etching such as reactive ion etching (RIE), as illustrated in FIG. 12. Instead of the oxide film 23, a photoresist film may be used as a mask for ion implantation.

The trench 10 penetrates the source expansion part 71 and the base region 6 so as to further dig down into the upper part of the current spreading layer 3 to reach the gate bottom protection region 4b. The provision of the trench 10 divides the source expansion part 71 into the respective source expansion parts 71a and 71b, and divides the base region 6 into the respective base regions 6a and 6b. The source expansion parts 71a and 71b and the source contact parts 72a and 72b implement the respective source regions 7a and 7b. The oxide film 23 used as the mask for etching is then removed.

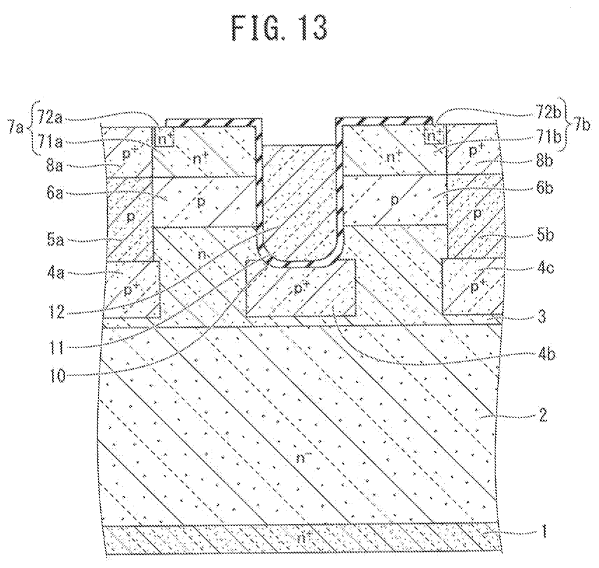

Next, a step of forming a gate insulating film/a gate electrode in step S16 shown in FIG. 4 is executed. The step of forming the gate insulating film/the gate electrode forms the gate insulating film 11 (refer to FIG. 13) on the respective bottom and side surfaces of the trench 10 and the respective top surfaces of the source contact parts 72a and 72b and the base contact regions 8a and 8b by CVD, high temperature oxidation (HTO), or thermal oxidation, for example. Upon the formation of the gate insulating film 11, heat treatment (PDA: post deposition annealing) is executed at a temperature in a range of about 900° C. or higher and 1350° C. or lower, for example.

Next, a polysilicon layer (a doped polysilicon layer) heavily doped with impurity ions such as phosphorus (P) or boron (B) is deposited to fill the inside of the trench 10 by CVD or the like. A part of the polysilicon layer and a part of the gate insulating film 11 are then selectively removed by photolithography and dry etching. This step provides the insulated gate electrode structure (11, 12) implemented by the gate insulating film 11 and the gate electrode 12, as illustrated in FIG. 13. The drop amount do of the gate electrode 12 may be adjusted in this step such that the top surface of the gate electrode 12 in contact with the gate insulating film 11 is located at a position shallower than the bottom surface of the source contact part 72a, as illustrated in FIG. 2.

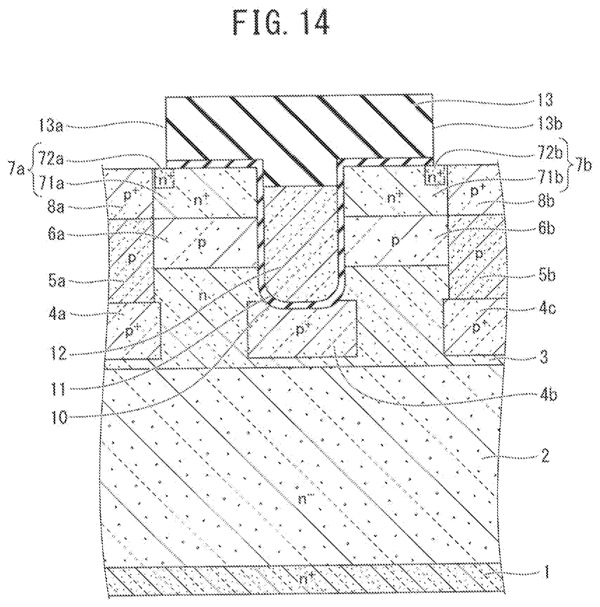

Next, the interlayer insulating film 13 (refer to FIG. 14) is deposited on the top surface of the insulated gate electrode structure (11, 12) by CVD or the like. A part of the interlayer insulating film 13 is then selectively removed by photolithography and dry etching so as to open the contact holes 13a and 13b in the interlayer insulating film 13 to which at least a part of the respective top surfaces of the source contact parts 72a and 72b and the base contact regions 8a and 8b is exposed, as illustrated in FIG. 14. This step may be followed by heat treatment (reflowing) for flattening the interlayer insulating film 13.

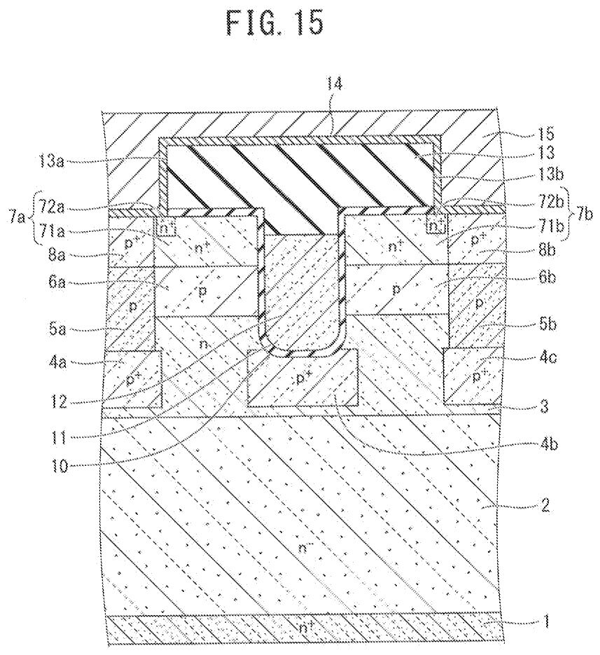

Next, the barrier metal layer 14 and the source wiring electrode 15 are sequentially formed to cover the top surface and the side surfaces of the interlayer insulating film 13 and the respective top surfaces of the source contact parts 72a and 72b and the base contact regions 8a and 8b so as to form the source electrode (14, 15) by sputtering or vapor deposition, for example, as illustrated in FIG. 15. The barrier metal layer 14 is to be in ohmic contact with the source contact parts 72a and 72b of the source regions 7a and 7b and the base contact regions 8a and 8b at a low resistance. While each of the source contact parts 72a and 72b and the base contact regions 8a and 8b is connected to the source electrode (14, 15) via the respective contact holes 13a and 13b, the source contact parts 72a and 72b and the base contact regions 8a and 8b may be connected to the source electrode (14, 15) via independent contact holes.

Next, the SiC substrate 1 is ground from the bottom surface side by grinding or chemical mechanical polishing (CMP) or the like to adjust the thickness as necessary so as to form the drain region 1. Thereafter, the drain electrode 16 (refer to FIG. 1) including gold (Au) is formed on the entire bottom surface of the drain region 1 by sputtering or vapor deposition, for example. The SiC semiconductor device illustrated in FIG. 1 is thus completed.

The method of manufacturing the SiC semiconductor device according to the first embodiment can provide the trench-gate SiC semiconductor device having the configuration capable of leading the source regions 7a and 7b to be in ohmic contact with the source electrode (14, 15) and capable of avoiding a lead current between the gate electrode 12 and the source regions 7a and 7b.

### Second Embodiment

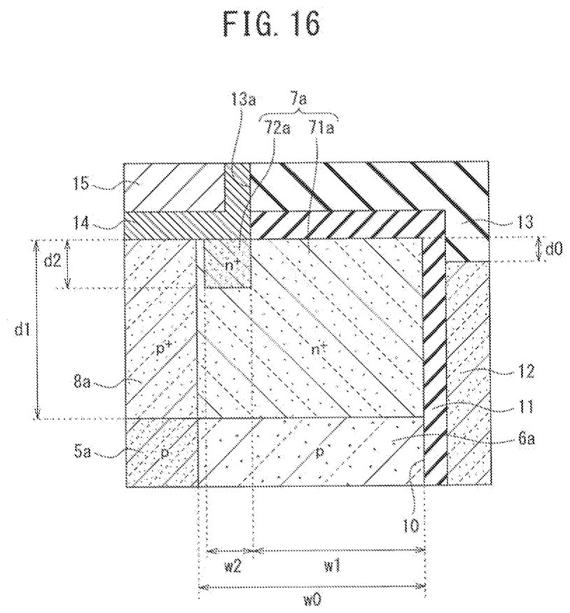

FIG. 16 is a cross-sectional view illustrating a SiC semiconductor device according to a second embodiment, and corresponds to the cross-sectional view of FIG. 2 illustrating the SiC semiconductor device according to the first embodiment. As illustrated in FIG. 16, the SiC semiconductor device according to the second embodiment differs from the SiC semiconductor device according to the first embodiment illustrated in FIG. 2 in that the end part (the side surface) of the n′-type source contact part 72a toward the gate electrode 12 substantially conforms to the end part of the interlayer insulating film 13 toward the contact hole 13a, which is the end part of each of the gate insulating film 11 and the interlayer insulating film 13. The other configurations of the SiC semiconductor device according to the second embodiment are the same as those of the SiC semiconductor device according to the first embodiment, and overlapping explanations are not repeated below.

The SiC semiconductor device according to the second embodiment is a trench-gate SiC semiconductor device having the configuration capable of leading the source regions 7a and 7b to be in ohmic contact with the source electrode (14, 15) and capable of avoiding a lead current between the gate electrode 12 and the source regions 7a and 7b, as in the case of the SiC semiconductor device according to the first embodiment.

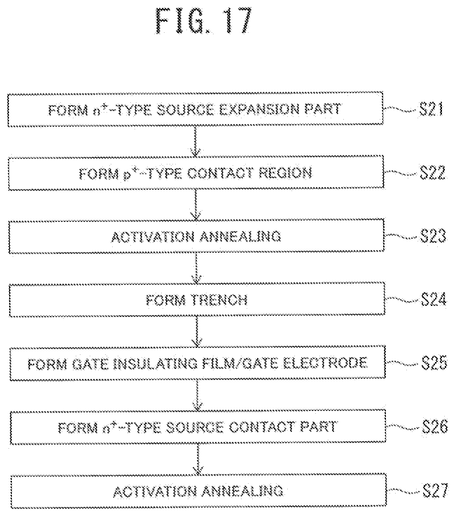

A method of manufacturing the SiC semiconductor device according to the second embodiment differs from the method of manufacturing the SiC semiconductor device according to the first embodiment shown in FIG. 4 in executing a step of forming an n′-type source contact part in step S26 after a step of forming a gate insulating film/a gate electrode in step S25, and in executing a step of activation annealing for a region to which impurity ions are implanted other than the source contact parts 72a and 72b in step S23 separately from a step of activation annealing for the source contact parts 72a and 72b in step S27, as shown in FIG. 17.

The steps before a step of forming an n′-type source expansion part in step S21 shown in FIG. 17 are substantially the same as those in the method of manufacturing the SiC semiconductor device according to the first embodiment, and overlapping explanations are not repeated below. The step of forming the n⁺-type source expansion part in step S21 shown in FIG. 17 is the same as the step of forming the n⁺-type source expansion part in step S11 shown in FIG. 4, and forms the n⁺-type source expansion part 71 by the implantation of the n-type impurity ions, as illustrated in FIG. 9.

A step of forming a p⁺-type contact region in step S22 shown in FIG. 17 is the same as the step of forming the p⁺-type contact region in step S13 shown in FIG. 4, and forms the respective p⁺-type base contact regions 8a and 8b by the implantation of the p-type impurity ions, as illustrated in FIG. 11. The respective n⁺-type source contact parts 72a and 72b at this point are not formed yet.

A step of activation annealing in step S23 shown in FIG. 17 is the same as the step of the activation annealing in step S14 shown in FIG. 4, and executes the activation annealing at a temperature of about 1600° C. or higher and 1900° C. or lower, for example, so as to collectively activate the p-type impurity ions or the n-type impurity ions implanted into the first buried regions 4a and 4c, the gate bottom protection region 4b, the second buried regions 5a and 5b, the source expansion part 71, the base contact regions 8a and 8b, and the like. The respective n⁺-type source contact parts 72a and 72b at this point are not formed yet.

A step of forming a trench in step S24 shown in FIG. 17 is the same as the step of forming the trench in step S15 shown in FIG. 4, and selectively forms the trench 10 from the top surface of the source expansion part 71 in the depth direction by dry etching or the like, as illustrated in FIG. 12. The respective n⁺-type source contact parts 72a and 72b at this point are not formed yet.

A step of forming a gate insulating film/a gate electrode in step S25 shown in FIG. 17 is the same as the step of forming the gate insulating film/the gate electrode in step S16 shown in FIG. 4, and buries the insulated gate electrode structure (11, 12) implemented by the gate insulating film 11 and the gate electrode 12 inside the trench 10, as illustrated in FIG. 13. The respective n′-type source contact parts 72a and 72b at this point are not formed yet.

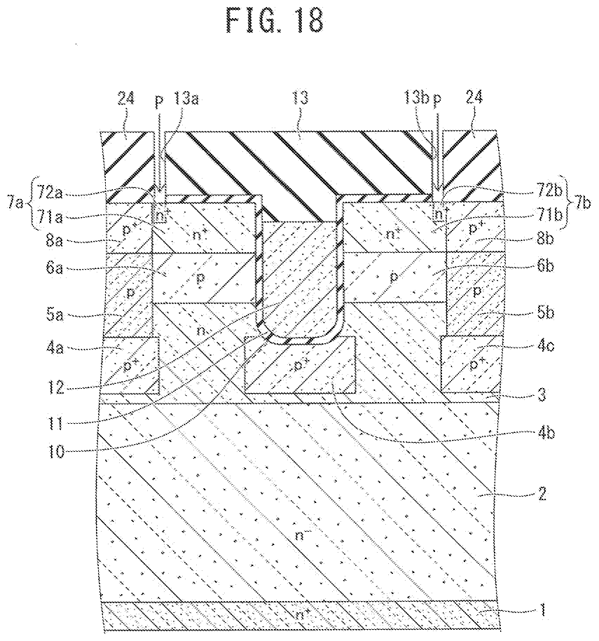

A step of forming an n⁺-type source contact part in step S26 shown in FIG. 17 deposits the interlayer insulating film 13 (refer to FIG. 18), and selectively removes a part of the interlayer insulating film 13 by photolithography and dry etching so as to open the contact holes 13a and 13b in the interlayer insulating film 13 to which the respective top surfaces of the source contact parts 72a and 72b and the base contact regions 8a and 8b are exposed. A photoresist film 24 is then delineated to cover the respective top surfaces of the base contact regions 8a and 8b by photolithography or the like. As illustrated in FIG. 18, using the interlayer insulating film 13 and the photoresist film 24 each as a mask for ion implantation, n-type impurity ions or an inactive element is implanted so as to form the n⁺-type source contact parts 72a and 72b in a self-aligned manner. The damage caused by the ion implantation breaks 4H—SiC included in the source contact parts 72a and 72b so as to provide the amorphous structure. The photoresist film 24 used as the mask for ion implantation is then removed. When the inactive element is used for the ion implantation, the impurity ions may be implanted further to the base contact regions 5a and 8b without the photoresist film 24 delineated.

A step of activation annealing in step S27 shown in FIG. 17 executes the activation annealing at a temperature lower than that in the step of the activation annealing in step S23 shown in FIG. 17, which is in a range of about 1000° C. or higher and 1500° C. or lower, for example, so as to activate the n-type impurity ions implanted into the source contact parts 72a and 72b. The activation annealing may be executed in an annealing furnace or executed by laser annealing. When the laser annealing is used, a metallic film such as titanium (Ti) or aluminum (Al) may be deposited so as to be irradiated with a laser beam from the top surface side. The metallic film may be removed after the laser annealing, or may be used as a constituent element of the source electrode (14, 15). This step recrystallizes the amorphous structure in the source contact parts 72a and 72b to lead to 3C—SiC so as to form the source contact parts 72a and 72b including 3C—SiC.

The following steps after the activation annealing step in step S27 in FIG. 17 are substantially the same as those of the method of manufacturing the SiC semiconductor device according to the first embodiment, and overlapping explanations are not repeated below.

The method of manufacturing the SiC semiconductor device according to the second embodiment can provide a trench-gate SiC semiconductor device having the configuration capable of leading the source regions 7a and 7b to be in ohmic contact with the source electrode (14, 15) and capable of avoiding a lead current between the gate electrode 12 and the source regions 7a and 7b, as in the case of the method of manufacturing the SiC semiconductor device according to the first embodiment.

The method of manufacturing the SiC semiconductor device according to the second embodiment uses the interlayer insulating film 13 as a mask after opening the contact holes 13a and 13b in the interlayer insulating film 13 to execute the implantation of the n-type impurity ions in the step of forming the n⁺-type source contact part in step S26 shown in FIG. 17 so as to form the respective n⁺-type source contact parts 72a and 72b in a self-aligned manner. This can avoid a displacement of the positions of the source contact parts 72a and 72b.

### Third Embodiment

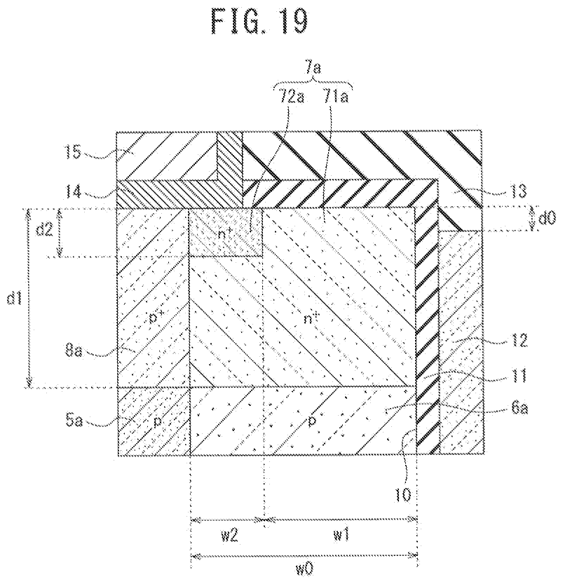

FIG. 19 is a cross-sectional view illustrating a SiC semiconductor device according to a third embodiment, and corresponds to the cross-sectional view of FIG. 2 illustrating the SiC semiconductor device according to the first embodiment. As illustrated in FIG. 19, the SiC semiconductor device according to the third embodiment differs from the SiC semiconductor device according to the first embodiment illustrated in FIG. 2 in that the end part (the side surface) of the n⁺-type source contact part 72a toward the base contact region 8a is in contact with the base contact region 8a. The other configurations of the SiC semiconductor device according to the third embodiment are the same as those of the SiC semiconductor device according to the first embodiment, and overlapping explanations are not repeated below.

The SiC semiconductor device according to the third embodiment is a trench-gate SiC semiconductor device having the configuration capable of leading the source regions 7a and 7b to be in ohmic contact with the source electrode (14, 15) and capable of avoiding a lead current between the gate electrode 12 and the source regions 7a and 7b, as in the case of the SiC semiconductor device according to the first embodiment.

### Other Embodiments

As described above, the invention has been described according to the first to third embodiments, but it should not be understood that the description and drawings implementing a portion of this disclosure limit the invention. Various alternative embodiments of the present invention, examples, and operational techniques will be apparent to those skilled in the art from this disclosure.

For example, while the first to third embodiments have been illustrated above with the case of using the MOSFET as the semiconductor device, the present invention can also be applied to an insulated gate bipolar transistor (IGBT) having a structure provided with a p⁺-type collector region, instead of the n⁺-type drain region 1. The present invention can further be applied to a reverse-conducting insulated gate bipolar transistor (RC-IGBT) or a reverse-blocking insulated gate bipolar transistor (RB-IGBT), instead of the simple IGBT.

Further, the configurations disclosed in the first to third embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A silicon carbide semiconductor device comprising:
a drift layer of a first conductivity-type including silicon carbide;
a base region of a second conductivity-type including silicon carbide provided on a top surface side of the drift layer;
a main region of the first conductivity-type including silicon carbide provided on a top surface side of the base region;
a gate insulating film provided inside a trench penetrating the main region and the base region;
a gate electrode buried inside the trench with the gate insulating film interposed; and
a main electrode provided in contact with the main region,
wherein the main region includes
a first region with a bottom surface in contact with the base region, and
a second region including a 3C structure and provided at an upper part of the first region separately from the gate insulating film inside the trench so as to be in contact with the main electrode.

2. The silicon carbide semiconductor device of claim 1, wherein a proportion of the 3C structure included in the second region is 10% or higher.

3. The silicon carbide semiconductor device of claim 1, wherein the second region includes phosphorus or arsenic.

4. The silicon carbide semiconductor device of claim 1, wherein the second region includes an inactive element.

5. The silicon carbide semiconductor device of claim 1, wherein the second region has an impurity concentration in a range of 1×10¹⁹ cm⁻³ or greater and 1×10²² cm⁻³ or less.

6. The silicon carbide semiconductor device of claim 1, wherein the first region interposed between the second region and the gate insulating film has a width of 100 nanometer or greater.

7. The silicon carbide semiconductor device of claim 1, wherein the second region has a width in a range of 300 nanometers or greater and 500 nanometers or smaller.

8. The silicon carbide semiconductor device of claim 1, wherein the second region has a depth from a top surface set in a range of 30 nanometers or greater and 100 nanometers or smaller.

9. The silicon carbide semiconductor device of claim 1, further comprising an interlayer insulating film provided on top surfaces of the gate electrode and the first region and having a contact hole to which at least a part of the second region is exposed,
wherein an end part of the second region toward the gate electrode is shifted from an end part of the contact hole toward the gate electrode.

10. The silicon carbide semiconductor device of claim 1, further comprising an interlayer insulating film provided on top surfaces of the gate electrode and the first region and having a contact hole to which at least a part of the second region is exposed,
wherein an end part of the second region toward the gate electrode conforms to a position of an end part of the contact hole.

11. The silicon carbide semiconductor device of claim 1, wherein a top surface of the gate electrode is located at a position shallower than a depth of the second region from a top surface.

12. The silicon carbide semiconductor device of claim 1, further comprising a base contact region of the second conductivity-type including silicon carbide provided on the top surface side of the base region so as to be in contact with the main region.

13. The silicon carbide semiconductor device of claim 12, wherein the second region is separated from the base contact region.

14. The silicon carbide semiconductor device of claim 1, wherein the first region has an impurity concentration in a range of 1×10¹⁶ cm⁻³ or greater and 1×10¹² cm⁻³ or less.

15. The silicon carbide semiconductor device of claim 1, wherein the first region includes nitrogen or phosphorus.

16. A method of manufacturing a silicon carbide semiconductor device, comprising:
forming a base region of a second conductivity-type including silicon carbide on a top surface side of a drift layer of a first conductivity-type including silicon carbide;
forming a main region of the first conductivity-type including silicon carbide on a top surface side of the base region;
digging a trench penetrating the main region and the base region;
forming a gate insulating film inside the trench;
burying a gate electrode inside the trench with the gate insulating film interposed; and
forming a main electrode so as to be in contact with the main region,
wherein the forming the main region includes
forming a first region of the first conductivity-type at an upper part of the base region, and
forming a second region including a 3C structure at an upper part of the first region separately from the gate insulating film inside the trench so as to be in contact with the main electrode.

17. The method of manufacturing the silicon carbide semiconductor device of claim 16, wherein the forming the main region includes
implanting impurity ions of the first conductivity-type to the upper part of the base region so as to form the first region,
implanting impurity ions or an inactive element of the first conductivity-type to the upper part of the first region so as to form the second region, and
executing activation annealing after forming the second region.

18. The method of manufacturing the silicon carbide semiconductor device of claim 17, wherein a total dose of the impurity ions implanted for forming the first region and for forming the second region is 2×10¹⁵ cm⁻² or greater.

19. The method of manufacturing the silicon carbide semiconductor device of claim 17, wherein a dose of the impurity ions implanted for forming the first region is less than 2×10¹⁵ cm⁻².

20. The method of manufacturing the silicon carbide semiconductor device of claim 16, further comprising:
depositing an interlayer insulating film on top surfaces of the first region, the second region, and the gate electrode; and
opening a contact hole in the interlayer insulating film so as to lead at least a part of the second region to be exposed,
wherein the forming the main region includes executing ion implantation by use of the interlayer insulating film as a mask after the opening the contact hole so as to form the second region in a self-aligned manner.
